(19) United States
(12) Patent Application Publication
(10) Pub. No.: US 2019/0115539 A1
(43) Pub. Date: Apr. 18, 2019

(54) ORGANIC LIGHT EMITTING DIODE STRUCTURE AND METHOD FOR MANUFACTURING THE SAME

(71) Applicant: CHUNGHWA PICTURE TUBES, LTD., Taoyuan City (TW)

(72) Inventors: Wen-Kuang TSAO, Taoyuan City (TW); Shin-Chuan CHIANG, Taipei City (TW); Der-Chun WU, Taipei City (TW); Yen-Yu HUANG, Taoyuan City (TW)

(21) Appl. No.: 15/826,631

(22) Filed: Nov. 29, 2017

(30) Foreign Application Priority Data
Oct. 13, 2017 (CN) 201710955105.6

(51) Int. Cl. H01L 51/00; H01L 27/32; H01L 51/52; H01L 51/50; H01L 51/56; G03F 7/038; G03F 7/039; G03F 7/075; G03F 7/16

(52) U.S. Cl. CPC H01L 51/0018; H01L 27/3246; H01L 51/5206; H01L 51/5221; H01L 51/5012; H01L 2251/303; G03F 7/038; G03F 7/039; G03F 7/0757; G03F 7/16; H01L 2251/301; H01L 51/56

(57) ABSTRACT

An organic light emitting diode includes a substrate, a bottom electrode, a first dielectric layer, a second dielectric layer, an organic light emitting layer, and a top electrode. The bottom electrode is disposed on the substrate. The first dielectric layer is disposed on the bottom electrode and has a first opening. The second dielectric layer is disposed on the first dielectric layer and has a second opening. The second opening is aligned with the first opening and exposes a portion of an upper surface of the bottom electrode. The organic light emitting layer is disposed in the first opening and the second opening. The organic light emitting layer contact the potion of the upper surface of the bottom electrode. The top electrode covers the organic light emitting layer.

### RELATED APPLICATION

This application claims priority to China Application Serial Number 201710955105.6, filed Oct. 13, 2017, which is herein incorporated by reference.

### BACKGROUND

### Field of Invention

The present disclosure relates to an organic light emitting diode structure and a method for manufacturing the same. More particularly, the present disclosure relates to an organic light emitting diode structure which may increase the photoresist adhesion in the lithography process and a method for manufacturing the same.

### Description of Related Art

The organic light emitting diode (OLED) includes the advantages of LCDs such as lightness, power saving, and high resolution as well as the advantages of LED such as active illumination, high response time, power saving, and cold light source. OLEDs are further advantageous in simple processes and the ease of color adjustment, and being able to implement to the flexible panel. Thus, the application of the organic light emitting diode is comprehensive. However, in the process of exposure using a photoresist, the photoresist is easily peeled off due to the insufficient adhesion between the photoresist and the dielectric layer, resulting in poor quality of OLED production and a decrease in the manufacture yield.

### SUMMARY

The present disclosure provides an organic light emitting diode structure, which is capable of increasing the adhesion of the photoresistor during the photolithographic processes. The organic light emitting diode structure includes a substrate, a bottom electrode, a first dielectric layer, a second dielectric layer, an organic light emitting layer, and a top electrode. The bottom electrode is disposed on the substrate. The first dielectric layer is disposed on the bottom electrode and has a first opening. The second dielectric layer is disposed on the first dielectric layer and has a second opening. The second opening is aligned with the first opening and exposes a portion of an upper surface of the bottom electrode. The organic light emitting layer is disposed in the first opening and the second opening. The organic light emitting layer contact the potion of the upper surface of the bottom electrode. The top electrode covers the organic light emitting layer.

In some embodiments of the present disclosure, a material of the first dielectric layer is silicon nitride.

In some embodiments of the present disclosure, a material of the second dielectric layer is silicon oxide.

In some embodiments of the present disclosure, a bottom width of the first opening is less than a top width of the second opening.

In some embodiments of the present disclosure, the organic light emitting layer includes an edge having a sidewall and an upper surface, and the sidewall of the edge and the upper surface of the edge form a right angle.

The present disclosure provides a method for manufacturing an organic light emitting diode structure. The method includes the operations described below. A substrate is firstly provided. A bottom electrode is formed on the substrate. A first dielectric layer is formed on the bottom electrode. A second dielectric layer is formed on and covers the first dielectric layer. A patterned mask layer is formed on the second dielectric layer. The patterned mask layer has an aperture exposing a portion of an upper surface of the second dielectric layer. Next, the first dielectric layer and the second dielectric layer under the aperture are removed to form an opening exposing a portion of an upper surface of the bottom electrode. An organic light emitting layer is deposited in the opening. The organic light emitting layer covers the exposed portion of the upper surface of the bottom electrode. Next, the patterned mask layer is removed. A top electrode is formed on the organic light emitting layer.

In some embodiments of the present disclosure, a material of the first dielectric layer is silicon nitride.

In some embodiments of the present disclosure, a material of the second dielectric layer is silicon oxide.

In some embodiments of the present disclosure, a bottom width of the opening is less than a top width of the opening.

In some embodiments of the present disclosure, the organic light emitting layer includes an edge having a sidewall and an upper surface, and the sidewall of the edge and the upper surface of the edge form a right angle.

In some embodiments of the present disclosure, the patterned mask layer is substantially free of water.

In some embodiments of the present disclosure, the step of removing the patterned mask layer includes applying an organic solvent which is substantially free of water to dissolve or strip the patterned mask layer.

### BRIEF DESCRIPTION OF THE DRAWINGS

The invention can be more fully understood by reading the following detailed description of the embodiment, with reference made to the accompanying drawings as follows:

FIG. 1 is a cross-sectional view illustrating one stage of manufacturing the organic light emitting diode structure in accordance with various embodiments of the present disclosure.

FIG. 2 is a cross-sectional view illustrating one stage of manufacturing the organic light emitting diode structure in accordance with various embodiments of the present disclosure.

FIG. 3 is a cross-sectional view illustrating one stage of manufacturing the organic light emitting diode structure in accordance with various embodiments of the present disclosure.

FIG. 4 is a cross-sectional view illustrating one stage of manufacturing the organic light emitting diode structure in accordance with various embodiments of the present disclosure.

FIG. 5A is a top view image after the formation of the photoresist layer in accordance with various embodiments of the present disclosure.

FIG. 5B is a top view image after the formation of the photoresist layer in accordance with comparative examples of the present disclosure.

FIG. 6 is a cross-sectional view illustrating one stage of manufacturing the organic light emitting diode structure in accordance with various embodiments of the present disclosure.

FIG. 7 is a cross-sectional view illustrating one stage of manufacturing the organic light emitting diode structure in accordance with various embodiments of the present disclosure.

FIG. 8 is a cross-sectional view illustrating one stage of manufacturing the organic light emitting diode structure in accordance with various embodiments of the present disclosure.

FIG. 9 is a cross-sectional view illustrating the organic light emitting diode structure in accordance with various embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

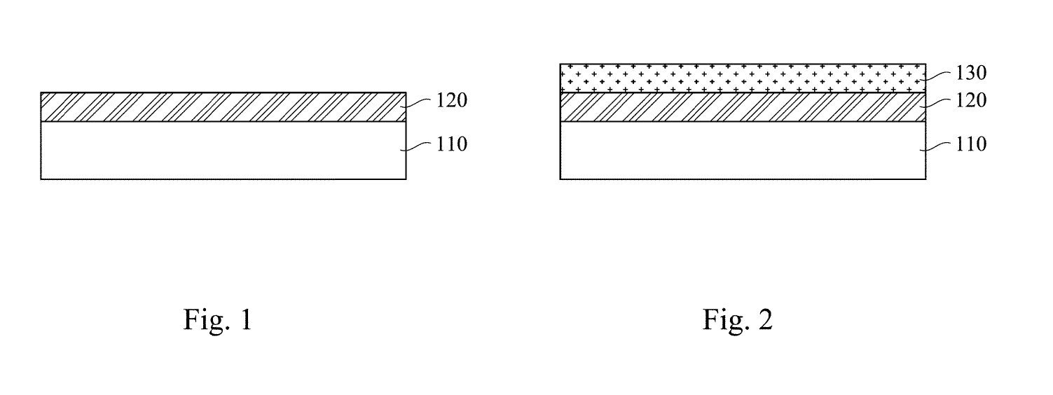

FIG. 1 through FIG. 9 are cross-sectional views illustrating different stages of manufacturing a light emitting diod structure in accordance with various embodiments of the present disclosure. Referring to FIG. 1, a substrate 110 is provided, and a bottom electrode 120 is formed on the substrate 110. In some embodiments, the substrate 110 may be a flexible substrate or a rigid substrate. For example, the material of the flexible substrate may be polyethylene terephthalate (PET) or polyimide, and the material of the rigid substrate may be glass. In some embodiments, the bottom electrode 120 may be a transparent electrode or an opaque electrode. For example, the material of the transparent electrode includes metal oxide such as indium tin oxide (ITO), indium zinc oxide (IZO), aluminum tin oxide (AITO), aluminum zinc oxide (AIZO), or indium gallium zinc oxide (IGZO), or other suitable oxides. The material of the opaque electrode includes gold, aluminum, copper, chromium, molybdenum, or tantalum or alloys of the metals described above, for example. In some embodiments, the bottom electrode 120 is formed on the substrate 110 by sputtering processes, thermal evaporation processes, thermal deposition processes, ion beam deposition processes, or physical vapor deposition processes.

Referring to FIG. 2, the first dielectric layer 130 is formed on the bottom electrode 120 after completing the structure illustrated in FIG. 1. In some embodiments, the material of the first dielectric layer 130 is silicon nitride (SiₓN_{y}). In some embodiments, the first dielectric layer 130 is formed on the bottom electrode 120 by chemical vapor deposition processes (CVD) or spin on dielectric processes (SOD).

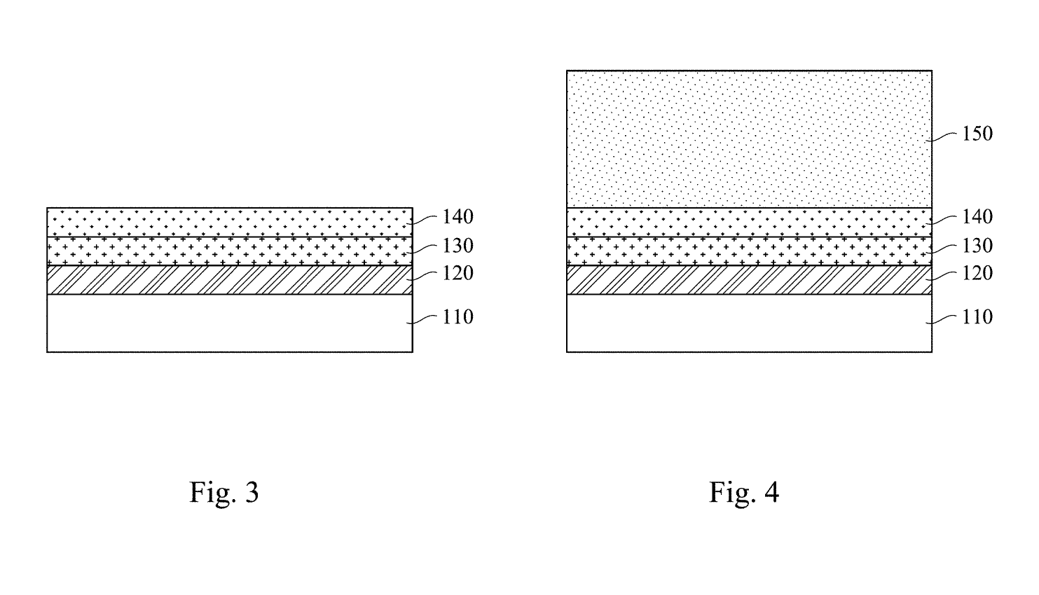

Referring to FIG. 3, the second dielectric layer 140 is formed to cover the first dielectric layer 130 after completing the structure illustrated in FIG. 2. In some embodiments, the material of the second dielectric layer 140 is silicon oxide (SiₓO_{y}). In some embodiments, the second dielectric layer 140 is formed on the first dielectric layer 130 by chemical vapor deposition processes (CVD) or spin on dielectric processes (SOD). To be specific, the second dielectric layer 140 has a thickness ranged from about 1 nm to about 9000 nm. According to various embodiments, when the thickness of the second dielectric layer 140 is greater than a certain value such as 9000 nm, the difficulty of subsequent process of forming the opening may be increased and the manufacturing cost may also be increased. On the contrary, when the thickness of the second dielectric layer 140 is less than a certain value such as 1 nm, the adhesion between the second dielectric layer 140 and the subsequent photoresist layer 150 may be insufficient. Therefore, the thickness of the second dielectric layer 140 may be 500 nm, 1000 nm, 1500 nm, 2000 nm, 2500 nm, 3000 nm, 3500 nm, 4000 nm, 4500 nm, 5000 nm, 5500 nm, 6000 nm, 6500 nm, 7000 nm, 7500 nm, 8000 nm, or 8500 nm, for example.

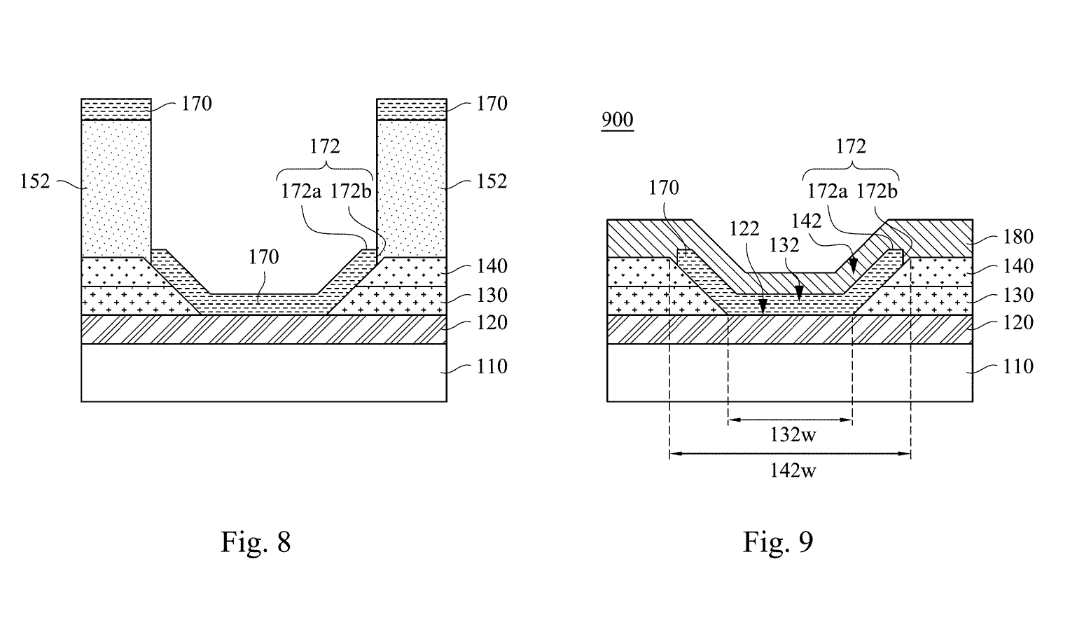

Next, referring to FIG. 4, according to some embodiments of the present disclosure, a photoresist layer 150 is formed fully covering the second dielectric layer 140. In some embodiments, the photoresist layer 150 may be a positive photoresistor or a negative photoresistor. The material of the photoresist layer 150 includes at least one polymer having an oxygen bonded thereon, but said polymer substantially does not includes water molecules. More specifically, the polymer having the oxygen may form silicon-oxygen bonds (Si—O) with the silicon atoms on the surface of the second dielectric layer 140 (e.g., silicon oxide layer) so that each silicon atom may be bonded with four oxygen atoms adjacent thereto so as to increase the adhesion between the second dielectric layer 140 (e.g., silicon oxide layer) and the photoresist layer. In some embodiments, it is noted that after performing a patterning process on the photoresist layer 150 to form a patterned mask layer 152. The patterned mask layer 152 may contact a portion of the organic light emitting layer 170 (shown in FIG. 8) subsequently formed, and the details will be described in more detail below. In order not to damage the organic light emitting layer 170, the composition of the photoresist layer 150 does not include water.

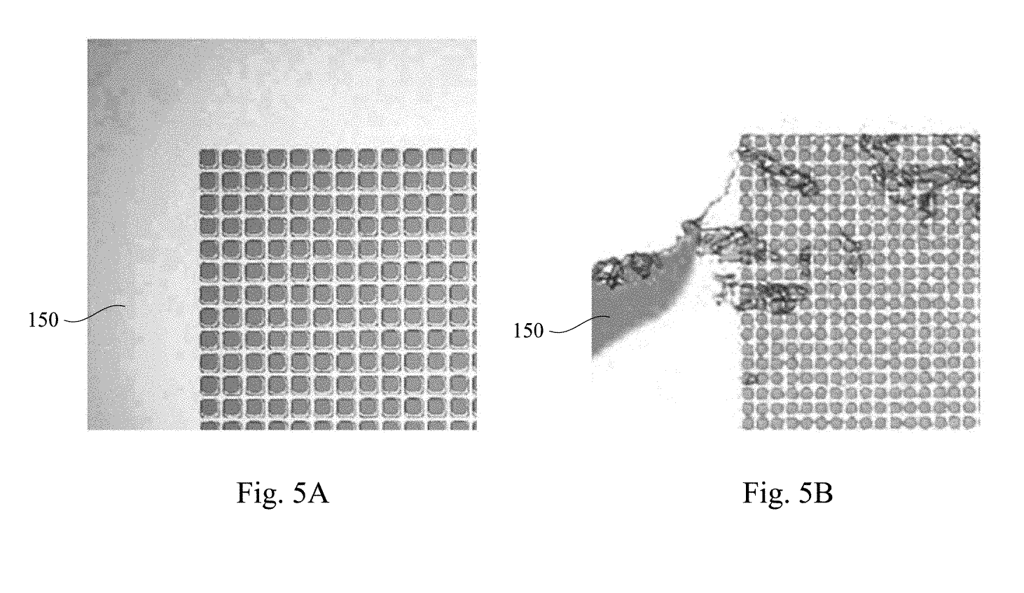

Referring to FIG. 5A, illustrated therein is a top view image after the formation of the photoresist layer in accordance with various embodiments of the present disclosure. FIG. 5A shows that the photoresist layer 150 is formed on the second dielectric layer 140 and has a good adhesion. FIG. 5B is a top view image after the formation of the photoresist layer in accordance with the comparative example of the present disclosure. The difference between the structure of the comparative example shown in FIG. 5B and the structure shown in FIG. 5A is that the photoresist layer 150 associated with FIG. 5B is formed directly on the first dielectric layer 130. In FIG. 5B, the photoresist layer 150 is prone to peeling off the first dielectric layer 130. More specifically, the waterproofness of the first dielectric layer 130 (silicon nitride layer) is better than the waterproofness of the second dielectric layer 140 (silicon oxide layer), but the adhesion between the first dielectric layer 130 (silicon nitride layer) and the photoresist layer 150 is poor than the adhesion between the second dielectric layer 140 (silicon oxide layer) and the photoresist layer 150. Therefore, in the method for manufacturing the organic light emitting diode structure provided herein, the second dielectric layer 140 (silicon oxide layer) cannot replace the first dielectric layer 130 (silicon nitride layer), and the second dielectric layer 140 (silicon oxide layer) has to be disposed between the first dielectric layer 130 (silicon nitride layer) and the photoresist layer 150.

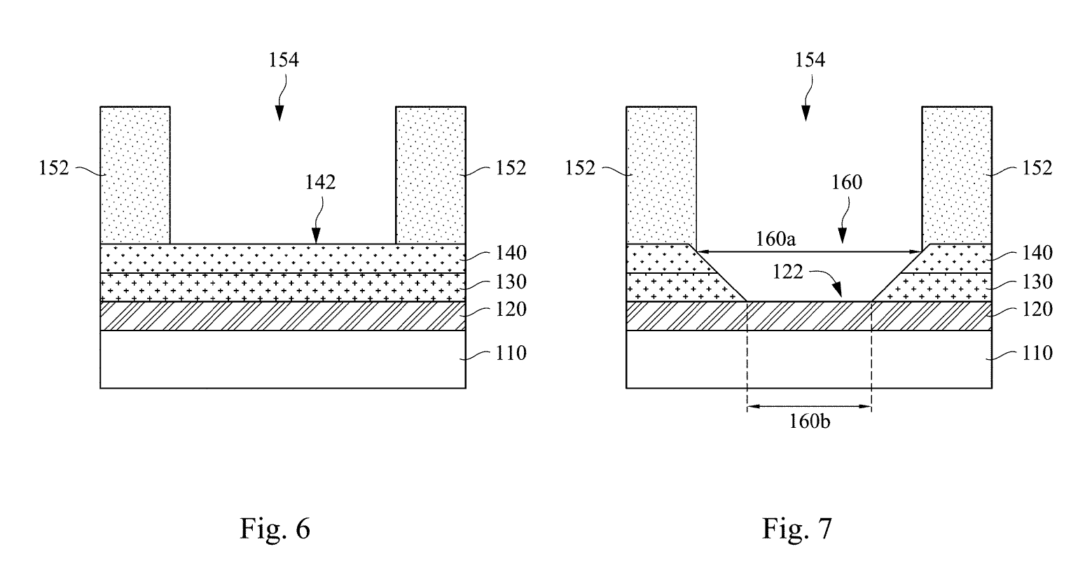

Next, referring to FIG. 6, the photoresist layer 150 disposed on the second dielectric layer 140 is patterned so as to form a patterned mask layer 152. To be specific, the patterned mask layer 152 has an aperture 154 exposing a portion 142 of the upper surface of the second dielectric layer 140.

Referring to FIG. 7, after completing the structure illustrated in FIG. 6, the first and second dielectric layer 130, 140 under the aperture 154 of the patterned mask layer 152 are removed so as to form an opening 160 exposing a portion 122 of the top surface of the bottom electrode 120. In some embodiments, the way to remove the first and second dielectric layer 130, 140 may be a dry etching process or a wet etching process. In one embodiment of the present disclosure, the top width 160a of the opening 160 is greater than the bottom width 160b thereof.

Referring to FIG. 8, an organic light emitting layer 170 is deposited in the opening 160 after completing the structure as illustrated in FIG. 7. The organic light emitting layer 170 covers the exposed potion 122 of the top surface of the bottom electrode 120. More specifically, the organic light emitting layer 170 is deposited in the opening 160 and on the patterned mask layer 152. In some embodiments, the organic light emitting layer 170 may be a red light emitting layer, a green light emitting layer, or a blue light emitting layer. In some embodiments, the material of the organic light emitting layer 170 includes polyethylene (PA), polyaniline (PAn), poly-para benzene (PPP), or polystyrene (PPV), for example. In some embodiments, the method of depositing the organic light emitting layer 170 in the opening 160 may be a chemical vapor deposition process or other suitable processes. In one embodiment of the present disclosure, the organic light emitting layer 170 has an edge 172 comprised of a sidewall 172b and an upper surface 172a. The sidewall 172b and the upper surface 172a of the edge 172 form a substantially right angle. Next, the patterned mask layer 152 and the portion of organic light emitting layer 170 thereon are removed. In various embodiments, the step of removing the patterned mask layer 152 includes applying an organic solvent, which is substantially free of water, to dissolve or strip the patterned mask layer 152. The reason of using organic solvent free of water is that the water-free organic solvent is less harmful to the organic light emitting layer 170 as compared with aqueous solution.

Next, referring to FIG. 9, a top electrode 180 is formed on the organic light emitting layer 170. In some embodiments, the top electrode 180 may be a transparent electrode or an opaque electrode. For example, the material of the transparent electrode incudes metal oxide such as indium tin oxide (ITO), indium zinc oxide (IZO), aluminum tin oxide (AITO), aluminum zinc oxide (AIZO), or indium gallium zinc oxide (IGZO), or other suitable oxides. The material of the opaque electrode incudes gold, aluminum, copper, chromium, molybdenum, tantalum or alloys of the metals above, for example. In some embodiments, the top electrode 180 is formed on the organic light emitting layer 170 by a sputtering process, a thermal evaporation process, a thermal deposition process, an ion beam deposition process, or other suitable physical vapor deposition processes.

According to another aspect of the present disclosure, an organic light emitting diode structure 900 is provided. FIG. 9 is a cross-sectional view of the organic light emitting diode structure 900 in accordance with various embodiments of the present disclosure. The organic light emitting diode structure 900 includes a substrate 110, a bottom electrode 120, a first dielectric layer 130, a second dielectric layer 140, an organic light emitting layer 170, and a top electrode 180. The bottom electrode 120 is disposed on the substrate 110. The first dielectric layer 130 is disposed on the bottom electrode 120 and has a first opening 132. In some embodiments, the first dielectric layer 130 is a silicon nitride layer (SiₓN_{y}). The second dielectric layer 140 is disposed on the first dielectric layer 130 and has a second opening 142. In some embodiments, the second dielectric layer 140 is a silicon oxide layer (SiₓO_{y}). To be specific, the second opening 142 is aligned with the first opening 132 and exposes a portion 122 of an upper surface of the bottom electrode 120. In one embodiment of the present disclosure, a bottom width 132w of the first opening 132 is less than a top width 142w of the second opening 142. The organic light emitting layer 170 is disposed in the first opening 132 and the second opening 142, and the organic light emitting layer 170 at least contact the exposed portion 122 of the upper surface of the bottom electrode 120. In one embodiment of the present disclosure, an edge 172 of the organic light emitting layer 170 has a sidewall 172b and an upper surface 172a. The sidewall 172b and the upper surface 172a of the edge 172 form a substantially right angle. The top electrode 180 covers the organic light emitting layer 170.

The disclosed organic light emitting diode structure and the method for manufacturing the same are advantageous in that the photoresist layer has a good adhesion to the second dielectric layer (e.g., silicon oxide layer) in the lithography process, and the resolution and the manufacturing yield of the organic light emitting diode may also be improved.

Although the present disclosure has been described in considerable detail with reference to certain embodiments thereof, other embodiments are possible. Therefore, the spirit and scope of the appended claims should not be limited thereto the description of the embodiments contained herein.

It will be apparent to those skilled in the art that various modifications and variations can be made to the structure of the present disclosure without departing from the scope or spirit of the invention. In view of the foregoing, it is intended that the present disclosure cover modifications and variations of this invention provided they fall within the scope of the following claims.

What is claimed is:

1. An organic light emitting diode structure, comprising:
a substrate;
a bottom electrode disposed on the substrate;
a first dielectric layer disposed on the bottom electrode and having a first opening;
a second dielectric layer disposed on the first dielectric layer and having a second opening, the second opening aligned with the first opening and exposing a portion of an upper surface of the bottom electrode;
an organic light emitting layer disposed in the first opening and the second opening, the organic light emitting layer contacting the portion of the upper surface of the bottom electrode; and
a top electrode covering the organic light emitting layer.

2. The organic light emitting diode structure of claim 1, wherein a material of the first dielectric layer is silicon nitride.

3. The organic light emitting diode structure of claim 1, wherein a material of the second dielectric layer is silicon oxide.

4. The organic light emitting diode structure of claim 1, wherein a bottom width of the first opening is less than a top width of the second opening.

5. The organic light emitting diode structure of claim 1, wherein the organic light emitting layer includes an edge having a sidewall and an upper surface, and the sidewall of the edge and the upper surface of the edge form a right angle.

6. A method for manufacturing an organic light emitting diode, the method comprising:
providing a substrate;
forming a bottom electrode on the substrate;
forming a first dielectric layer on the bottom electrode;
forming a second dielectric layer covering the first dielectric layer;
forming a patterned mask layer on the second dielectric layer, the patterned mask layer having an aperture exposing a portion of an upper surface of the second dielectric layer;
removing the first dielectric layer and the second dielectric layer under the aperture to form an opening exposing a portion of an upper surface of the bottom electrode;
depositing an organic light emitting layer in the opening, the organic light emitting layer covering the exposed portion of the upper surface of the bottom electrode;
removing the patterned mask layer; and
forming a top electrode on the organic light emitting layer.

7. The method of claim 6, wherein a material of the first dielectric layer is silicon nitride.

8. The method of claim 6, wherein a material of the second dielectric layer is silicon oxide.

9. The method of claim 6, wherein a bottom width of the opening is less than a top width of the opening.

10. The method of claim 6, wherein the organic light emitting layer includes an edge having a sidewall and an upper surface, and the sidewall and the upper surface of the edge form a right angle.

11. The method of claim 6, wherein the patterned mask layer is substantially free of water.

12. The method of claim 6, wherein the step of removing the patterned mask layer comprises applying an organic solvent which is substantially free of water to dissolve or strip the patterned mask layer.
